(19) United States
(12) Patent Application Publication
(10) Pub. No.: US 2025/0257445 A1
(43) Pub. Date: Aug. 14, 2025

(54) Coating Control System and Method of Controlling a Coating

(71) Applicant: Vitro Flat Glass LLC., Cheswick, PA (US)

(72) Inventors: Wei Xu, Cheswick, PA (US); Neil Curliss, Salem, OR (US); Zachary Dunlap, Woodburn, OR (US); Amanda Duong, Salem, OR (US); Aleksandr Gerasimenko, Wichita Falls, TX (US); Benjamin Gibbs, Allison Park, PA (US); Priyadarshi Mahapatra, Pittsburgh, PA (US); Russell W. Schrier, Oakmont, PA (US); Andrew V. Wagner, Pittsburgh, PA (US)

(21) Appl. No.: 19/046,969

(22) Filed: Feb. 6, 2025

Related U.S. Application Data
(60) Provisional application No. 63/551,692, filed on Feb. 9, 2024.
(60) Provisional application No. 63/691,721, filed on Sep. 6, 2024.

(51) Int. Cl. C23C 14/54; C03C 17/00; C23C 14/35

(52) U.S. Cl. CPC C23C 14/545; C03C 17/002; C23C 14/35; C03C 2218/156

(57) ABSTRACT

A computer-implemented method for automatically controlling a component of a coating applicator includes: identifying a first coated substrate including a substrate including a surface over which at least one coating layer is positioned, the at least one coating layer positioned over the surface using at least one applicator; in response to identifying the first coated substrate, determining a target coating profile corresponding to the first coated substrate; determining an actual coating profile for the first coated substrate; generating a deviation coating profile for the first coated substrate by comparing the target coating profile to the actual coating profile; inputting the deviation coating profile into a model based on experimental coating control data; and generating, with the model, at least one control instruction for adjusting at least one component of the at least one applicator based on the deviation coating profile prior to coating a second substrate according to the target coating profile.

### CROSS-REFERENCE TO RELATED APPLICATIONS

This application claims priority to U.S. Provisional Patent Application Nos. 63/551,692 filed Feb. 9, 2024, and 63/691,721 filed Sep. 6, 2024, the disclosures of which are hereby incorporated by reference in their entireties.

### BACKGROUND

### Field

The present disclosure is directed to a method for automatically controlling a component of a coating applicator. The present disclosure is also directed to a system for automatically controlling a component of a coating applicator.

### Technical Considerations

Existing systems for forming coated substrates manually control the thickness uniformity of the coatings being applied to the substrate. However, these systems can be unreliable, at least because they depend upon the experience of the operator manually controlling the coating applicator and taking suitable corrective action.

### SUMMARY OF THE DISCLOSURE

According to some non-limiting aspects of the disclosure, a computer-implemented method for automatically controlling a component of a coating applicator includes: identifying, with at least one processor, a first coated substrate including a substrate including a surface over which at least one coating layer is positioned, the at least one coating layer positioned over the surface using at least one applicator; in response to identifying the first coated substrate, determining, with at least one processor, a target coating profile corresponding to the first coated substrate; determining, with at least one processor, an actual coating profile for the first coated substrate; generating, with at least one processor, a deviation coating profile for the first coated substrate by comparing the target coating profile to the actual coating profile; inputting, with at least one processor, the deviation coating profile into a model based on experimental coating control data; and generating, with the model, at least one control instruction for adjusting at least one component of the at least one applicator based on the deviation coating profile prior to coating a second substrate according to the target coating profile.

In some non-limiting aspects, the computer-implemented method may further include: automatically adjusting, with at least one processor, the at least one component of the at least one applicator based on the at least one control instruction.

In some non-limiting aspects, the computer-implemented method may further include: displaying, with at least one processor, the at least one control instruction on a user interface of a computing device of a user.

In some non-limiting aspects, the substrate may include glass.

In some non-limiting aspects, the first coated substrate may include the surface over which a coating stack including a plurality of coating layers is positioned.

In some non-limiting aspects, the deviation coating profile may be determined after a first layer of the coating stack is positioned on the surface but before a second layer of the coating stack is positioned over the first layer.

In some non-limiting aspects, the deviation coating profile may be determined after the plurality of coating layers of the coating stack are positioned over the surface.

In some non-limiting aspects, determining the actual coating profile includes: taking, with at least one processor, at least one color measurement of the first coated substrate; inputting, with at least one processor, the at least one color measurement to a second model based on experimental color to thickness data; and generating, with the second model, the actual coating profile based on the at least one color measurement.

In some non-limiting aspects, the target coating profile and/or the actual coating profile may provide a target and/or actual coating thickness for at least one layer of the at least one coating layer relative to a position on the surface.

In some non-limiting aspects, the at least one applicator may include a vacuum coating applicator.

In some non-limiting aspects, the vacuum coating applicator may include at least one gas inlet through which at least one reactive or non-reactive gas is flowed to deposit the at least one coating layer on the surface, where the at least one control instruction may include a control instruction for adjusting a flow rate of the gas through the at least one gas inlet for depositing a coating layer on the second substrate according to the target coating profile.

In some non-limiting aspects, the vacuum coating applicator may include a magnet bar arranged at a height above the surface to deposit the at least one coating layer on the surface, where the at least one control instruction may include a control instruction for adjusting the height of the magnet bar above the surface for depositing a coating layer on the second substrate according to the target coating profile.

In some non-limiting aspects, the magnet bar may include a plurality of nodes configured to adjust a height of a section of the magnet bar above the surface, where the at least one control instruction may include a control instruction for only a subset of the plurality of nodes to adjust the height of a corresponding section of the magnet bar above the surface for depositing a coating layer on the second substrate according to the target coating profile.

In some non-limiting aspects, identifying the first coated substrate may include scanning an identifier associated with the first coated substrate.

In some non-limiting aspects, the first coated substrate may include the surface over which a coating stack including a plurality of coating layers is positioned, where a plurality of applicators may be provided, each applicator of the plurality of applicators configured to apply a different layer of the plurality of layers of the coating stack, where generating the at least one control instruction may include: determining, with the model, at least one applicator of the plurality of applicators requiring adjustment to obtain the target coating profile based on the deviation coating profile; and generating, with the model, the at least one control instruction for at least one component of the at least one applicator of the plurality of applicators requiring adjustment to obtain the target coating profile.

In some non-limiting aspects, not including a step of directly measuring a thickness of the at least one coating layer.

In some non-limiting aspects, the at least one control instruction may be generated in response to the model determining that at least a portion of the deviation coating profile satisfies a threshold.

In some non-limiting aspects, the computer-implemented method may further include: applying, with the adjusted at least one component of the at least one applicator, at least one second coating layer to a surface of the second substrate according to the target coating profile.

In some non-limiting aspects, the computer-implemented method may further include: automatically identifying, with at least one processor, at least one parameter of the at least one applicator and/or a parameter of a coating process for coating the substrate; and inputting the at least one parameter to the model, where the at least one control instructions may be generated by the model based on the at least one parameter.

In some non-limiting aspects, inputting the deviation coating profile into the model may include inputting coating profile data associated with a first layer of the plurality of layers and a second layer of the plurality of layers, where the at least one control instruction for adjusting the at least one component of the at least one applicator may be generated to cause the at least one applicator to apply a first layer of a plurality of layers on the second substrate based on the coating profile data associated with the first layer of the plurality of layers and the second layer of the plurality of layers.

In some non-limiting aspects, determining the actual coating profile for the first coated substrate may include determining a thickness of a first layer of the at least one coating layer, the determined thickness of the first layer of the at least one coating layer different from a thickness for the first layer of the at least one coating layer from the target coating profile, where the at least one control instruction for adjusting the at least one component of the at least one applicator may be generated to cause the at least one applicator to apply a first layer of at least one coating layer on the second substrate at a different thickness compared to the determined thickness of the first layer of the at least one coating layer from the first coated substrate.

In some non-limiting aspects, the first coated substrate may include a post-tempered substrate having the actual coating profile formed by heating a pre-tempered first substrate having a pre-tempered coating profile, where generating the at least one control instruction may include the model: receiving the input including the deviation coating profile; analyzing experimental coating control data including a plurality of historical pre-tempered coating profiles; determining a first historical pre-tempered coating profile from the plurality of historical pre-tempered coating profiles; and generating the at least one control instruction for adjusting the at least one component of the at least one applicator to cause the at least one applicator to apply the first historical pre-tempered coating profile to a pre-tempered second substrate.

In some non-limiting aspects, the computer-implemented method may further include: determining, with the model, that the at least one component of the at least one applicator is malfunctioning or satisfies a limit based on the deviation coating profile; and maintenancing the at least one component of the at least one applicator.

In some non-limiting aspects, the computer-implemented method may further include: in response to determining that the at least one component of the at least one applicator is malfunctioning or satisfies a limit based on the deviation coating profile, automatically updating the model based on the malfunctioning or satisfaction of the limit by generating a control instruction that distributes an adjustment to a remainder of components of the at least one applicator.

In some non-limiting aspects, the first coated substrate may include a post-tempered substrate having the actual coating profile formed by heating a pre-tempered first substrate having a pre-tempered coating profile, where generating the at least one control instruction may include the model: receiving the input including the deviation coating profile and the pre-tempered coating profile, the deviation coating profile comparing the target coating profile of the post-tempered substrate to the actual coating profile; comparing the pre-tempered coating profile to the actual coating profile; and generating the at least one control instruction for adjusting the at least one component of the at least one applicator based on the comparison of the pre-tempered coating profile to the actual coating profile.

According to some non-limiting aspects of the disclosure, a system for automatically controlling a component of a coating applicator includes: at least one applicator configured to prepare a first coated substrate including a substrate including a surface over which at least one coating layer is positioned; and a control system including at least one processor programmed or configured to: identify the first coated substrate; in response to identifying the first coated substrate, determine a target coating profile corresponding to the first coated substrate; determine an actual coating profile for the first coated substrate; generate a deviation coating profile for the first coated substrate by comparing the target coating profile to the actual coating profile; input the deviation coating profile into a model based on experimental coating control data; and generate, with the model, at least one control instruction for adjusting at least one component of the at least one applicator based on the deviation coating profile prior to coating a second substrate according to the target coating profile.

In some non-limiting aspects, the at least one component of the at least one applicator may include an adjustor, where the at least one processor may be programmed or configured to cause the adjustor to adjust the at least one component based on the at least one control instruction.

In some non-limiting aspects, the system may further include a computing device of a user, the computing device including a user interface configured to display the at least one control instruction.

In some non-limiting aspects, the system may further include: a measurement device configured to take at least one color measurement of the first coated substrate; and a second model based on experimental color to thickness data and to which the at least one color measurement is input, where the second model may be programmed or configured to generate the actual coating profile based on the at least one color measurement.

In some non-limiting aspects, the at least one applicator may include a vacuum coating applicator.

In some non-limiting aspects, the vacuum coating applicator may include at least one gas inlet through which at least one reactive or non-reactive gas is flowed to deposit the at least one coating layer on the surface, where the at least one control instruction may include a control instruction for adjusting a flow rate of the gas through the at least one gas inlet for depositing a coating layer on the second substrate according to the target coating profile.

In some non-limiting aspects, the vacuum coating applicator may include a magnet bar arranged at a height above the surface to deposit the at least one coating layer on the surface, where the at least one control instruction may include a control instruction for adjusting the height of the magnet bar above the surface for depositing a coating layer on the second substrate according to the target coating profile.

In some non-limiting aspects, the magnet bar may include a plurality of nodes configured to adjust a height of a section of the magnet bar above the surface, where the at least one control instruction may include a control instruction for only a subset of the plurality of nodes to adjust the height of a corresponding section of the magnet bar above the surface for depositing a coating layer on the second substrate according to the target coating profile.

In some non-limiting aspects, the system may further include a scanner configured to identify the first coated substrate by scanning an identifier associated with the first coated substrate.

In some non-limiting aspects, the first coated substrate may include the surface over which a coating stack comprising a plurality of coating layers is positioned, where the at least one applicator may include a plurality of applicators, each applicator of the plurality of applicators configured to apply a different layer of the plurality of layers of the coating stack, where generating the at least one control instruction may include: determining, with the model, at least one applicator of the plurality of applicators requiring adjustment to obtain the target coating profile based on the deviation coating profile; and generating, with the model, the at least one control instruction for at least one component of the at least one applicator of the plurality of applicators requiring adjustment to obtain the target coating profile.

In some non-limiting aspects, the system does not include a device for directly measuring a thickness of the at least one coating layer.

In some non-limiting aspects, the model may be programmed or configured to generate the at least one control instruction in response to determining that at least a portion of the deviation coating profile satisfies a threshold.

In some non-limiting aspects, the adjusted at least one component may be configured to apply at least one second coating layer to a surface of the second substrate according to the target coating profile.

In some non-limiting aspects, the at least one applicator may include a magnetron sputtering vapor deposition (MSVD) applicator.

In some non-limiting aspects, the first coated substrate may include the surface over which a coating stack including a plurality of coating layers is positioned, where inputting the deviation coating profile into the model may include inputting coating profile data associated with a first layer of the plurality of layers and a second layer of the plurality of layers, where the at least one control instruction for adjusting the at least one component of the at least one applicator may be generated to cause the at least one applicator to apply a first layer of a plurality of layers on the second substrate based on the coating profile data associated with the first layer of the plurality of layers and the second layer of the plurality of layers.

In some non-limiting aspects, determining the actual coating profile for the first coated substrate may include the at least one processor determining a thickness of a first layer of the at least one coating layer, the determined thickness of the first layer of the at least one coating layer different from a thickness for the first layer of the at least one coating layer from the target coating profile, where the at least one control instruction for adjusting the at least one component of the at least one applicator may be generated to cause the at least one applicator to apply a first layer of at least one coating layer on the second substrate at a different thickness compared to the determined thickness of the first layer of the at least one coating layer from the first coated substrate.

In some non-limiting aspects, the first coated substrate may include a post-tempered substrate having the actual coating profile formed by heating a pre-tempered first substrate having a pre-tempered coating profile, where generating the at least one control instruction may include the model: receiving the input including the deviation coating profile; analyzing experimental coating control data including a plurality of historical pre-tempered coating profiles; determining a first historical pre-tempered coating profile from the plurality of historical pre-tempered coating profiles; and generating the at least one control instruction for adjusting the at least one component of the at least one applicator to cause the at least one applicator to apply the first historical pre-tempered coating profile to a pre-tempered second substrate.

In some non-limiting aspects, the at least one processor may be further programmed or configured to determine, with the model, that the at least one component of the at least one applicator is malfunctioning or satisfies a limit based on the deviation coating profile, where the at least one component of the at least one applicator may be maintenanced based on the determination that the at least one component of the at least one applicator is malfunctioning or satisfies a limit.

In some non-limiting aspects, the at least one processor may be further programmed or configured to: in response to determining that the at least one component of the at least one applicator is malfunctioning or satisfies a limit based on the deviation coating profile, automatically update the model based on the malfunctioning or satisfaction of the limit by generating a control instruction that distributes an adjustment to a remainder of components of the at least one applicator.

In some non-limiting aspects, the first coated substrate may include a post-tempered substrate having the actual coating profile formed by heating a pre-tempered first substrate having a pre-tempered coating profile, where generating the at least one control instruction may include the model: receiving the input including the deviation coating profile and the pre-tempered coating profile, the deviation coating profile comparing the target coating profile of the post-tempered substrate to the actual coating profile; comparing the pre-tempered coating profile to the actual coating profile; and generating the at least one control instruction for adjusting the at least one component of the at least one applicator based on the comparison of the pre-tempered coating profile to the actual coating profile.

The following numbered clauses are illustrative of various aspects of the disclosure:

Clause 1: A computer-implemented method for automatically controlling a component of a coating applicator, comprising: identifying, with at least one processor, a first coated substrate comprising a substrate comprising a surface over which at least one coating layer is positioned, the at least one coating layer positioned over the surface using at least one applicator; in response to identifying the first coated substrate, determining, with at least one processor, a target coating profile corresponding to the first coated substrate; determining, with at least one processor, an actual coating profile for the first coated substrate; generating, with at least one processor, a deviation coating profile for the first coated substrate by comparing the target coating profile to the actual coating profile; inputting, with at least one processor, the deviation coating profile into a model based on experimental coating control data; and generating, with the model, at least one control instruction for adjusting at least one component of the at least one applicator based on the deviation coating profile prior to coating a second substrate according to the target coating profile.

Clause 2: The computer-implemented method of clause 1, further comprising: automatically adjusting, with at least one processor, the at least one component of the at least one applicator based on the at least one control instruction.

Clause 3: The computer-implemented method of clause 1 or 2, further comprising: displaying, with at least one processor, the at least one control instruction on a user interface of a computing device of a user.

Clause 4: The computer-implemented method of any of clauses 1-3, wherein the substrate comprises glass.

Clause 5: The computer-implemented method of any of clauses 1-4, wherein the first coated substrate comprises the surface over which a coating stack comprising a plurality of coating layers is positioned.

Clause 6: The computer-implemented method of clause 5, wherein the deviation coating profile is determined after a first layer of the coating stack is positioned on the surface but before a second layer of the coating stack is positioned over the first layer.

Clause 7: The computer-implemented method of clause 5, wherein the deviation coating profile is determined after the plurality of coating layers of the coating stack are positioned over the surface.

Clause 8: The computer-implemented method of any of clauses 1-7, wherein determining the actual coating profile comprises: taking, with at least one processor, at least one color measurement of the first coated substrate; inputting, with at least one processor, the at least one color measurement to a second model based on experimental color to thickness data; and generating, with the second model, the actual coating profile based on the at least one color measurement.

Clause 9: The computer-implemented method of any of clauses 1-8, wherein the target coating profile and/or the actual coating profile provide a target and/or actual coating thickness for at least one layer of the at least one coating layer relative to a position on the surface.

Clause 10: The computer-implemented method of any of clauses 1-9, wherein the at least one applicator comprises a vacuum coating applicator.

Clause 11: The computer-implemented method of clause 10, wherein the vacuum coating applicator comprises at least one gas inlet through which at least one reactive or non-reactive gas is flowed to deposit the at least one coating layer on the surface, wherein the at least one control instruction comprises a control instruction for adjusting a flow rate of the gas through the at least one gas inlet for depositing a coating layer on the second substrate according to the target coating profile.

Clause 12: The computer-implemented method of clause 10 or 11, wherein the vacuum coating applicator comprises a magnet bar arranged at a height above the surface to deposit the at least one coating layer on the surface, wherein the at least one control instruction comprises a control instruction for adjusting the height of the magnet bar above the surface for depositing a coating layer on the second substrate according to the target coating profile.

Clause 13: The computer-implemented method of clause 12, wherein the magnet bar comprises a plurality of nodes configured to adjust a height of a section of the magnet bar above the surface, wherein the at least one control instruction comprises a control instruction for only a subset of the plurality of nodes to adjust the height of a corresponding section of the magnet bar above the surface for depositing a coating layer on the second substrate according to the target coating profile.

Clause 14: The computer-implemented method of any of clauses 1-13, wherein identifying the first coated substrate comprises scanning an identifier associated with the first coated substrate.

Clause 15: The computer-implemented method of any of clauses 1-14, wherein the first coated substrate comprises the surface over which a coating stack comprising a plurality of coating layers is positioned, wherein a plurality of applicators are provided, each applicator of the plurality of applicators configured to apply a different layer of the plurality of layers of the coating stack, wherein generating the at least one control instruction comprises: determining, with the model, at least one applicator of the plurality of applicators requiring adjustment to obtain the target coating profile based on the deviation coating profile; and generating, with the model, the at least one control instruction for at least one component of the at least one applicator of the plurality of applicators requiring adjustment to obtain the target coating profile.

Clause 16: The computer-implemented method of any of clauses 1-15, not including a step of directly measuring a thickness of the at least one coating layer.

Clause 17: The computer-implemented method of any of clauses 1-16, wherein the at least one control instruction is generated in response to the model determining that at least a portion of the deviation coating profile satisfies a threshold.

Clause 18: The computer-implemented method of any of clauses 2-17, further comprising: applying, with the adjusted at least one component of the at least one applicator, at least one second coating layer to a surface of the second substrate according to the target coating profile.

Clause 19: The computer-implemented method of any of clauses 1-18, further comprising: automatically identifying, with at least one processor, at least one parameter of the at least one applicator and/or a parameter of a coating process for coating the substrate; and inputting the at least one parameter to the model, wherein the at least one control instructions is generated by the model based on the at least one parameter.

Clause 20: The computer-implemented method of any of clauses 5-19, wherein inputting the deviation coating profile into the model comprises inputting coating profile data associated with a first layer of the plurality of layers and a second layer of the plurality of layers, wherein the at least one control instruction for adjusting the at least one component of the at least one applicator is generated to cause the at least one applicator to apply a first layer of a plurality of layers on the second substrate based on the coating profile data associated with the first layer of the plurality of layers and the second layer of the plurality of layers.

Clause 21: The computer-implemented method of any of clauses 1-20, wherein determining the actual coating profile for the first coated substrate comprises determining a thickness of a first layer of the at least one coating layer, the determined thickness of the first layer of the at least one coating layer different from a thickness for the first layer of the at least one coating layer from the target coating profile, wherein the at least one control instruction for adjusting the at least one component of the at least one applicator is generated to cause the at least one applicator to apply a first layer of at least one coating layer on the second substrate at a different thickness compared to the determined thickness of the first layer of the at least one coating layer from the first coated substrate.

Clause 22: The computer-implemented method of any of clauses 1-21, wherein the first coated substrate comprises a post-tempered substrate having the actual coating profile formed by heating a pre-tempered first substrate having a pre-tempered coating profile, wherein generating the at least one control instruction comprises the model: receiving the input comprising the deviation coating profile; analyzing experimental coating control data comprising a plurality of historical pre-tempered coating profiles; determining a first historical pre-tempered coating profile from the plurality of historical pre-tempered coating profiles; and generating the at least one control instruction for adjusting the at least one component of the at least one applicator to cause the at least one applicator to apply the first historical pre-tempered coating profile to a pre-tempered second substrate.

Clause 23: The computer-implemented method of any of clauses 1-22, further comprising: determining, with the model, that the at least one component of the at least one applicator is malfunctioning or satisfies a limit based on the deviation coating profile; and maintenancing the at least one component of the at least one applicator.

Clause 24: The computer-implemented method of clause 23, further comprising: in response to determining that the at least one component of the at least one applicator is malfunctioning or satisfies a limit based on the deviation coating profile, automatically updating the model based on the malfunctioning or satisfaction of the limit by generating a control instruction that distributes an adjustment to a remainder of components of the at least one applicator.

Clause 25: The computer-implemented method of any of clauses 1-24, wherein the first coated substrate comprises a post-tempered substrate having the actual coating profile formed by heating a pre-tempered first substrate having a pre-tempered coating profile, wherein generating the at least one control instruction comprises the model: receiving the input comprising the deviation coating profile and the pre-tempered coating profile, the deviation coating profile comparing the target coating profile of the post-tempered substrate to the actual coating profile; comparing the pre-tempered coating profile to the actual coating profile; and generating the at least one control instruction for adjusting the at least one component of the at least one applicator based on the comparison of the pre-tempered coating profile to the actual coating profile.

Clause 26: A system for automatically controlling a component of a coating applicator, comprising: at least one applicator configured to prepare a first coated substrate comprising a substrate comprising a surface over which at least one coating layer is positioned; and a control system comprising at least one processor programmed or configured to: identify the first coated substrate; in response to identifying the first coated substrate, determine a target coating profile corresponding to the first coated substrate; determine an actual coating profile for the first coated substrate; generate a deviation coating profile for the first coated substrate by comparing the target coating profile to the actual coating profile; input the deviation coating profile into a model based on experimental coating control data; and generate, with the model, at least one control instruction for adjusting at least one component of the at least one applicator based on the deviation coating profile prior to coating a second substrate according to the target coating profile.

Clause 27: The system of clause 26, wherein the at least one component of the at least one applicator comprises an adjustor, wherein the at least one processor is programmed or configured to cause the adjustor to adjust the at least one component based on the at least one control instruction.

Clause 28: The system of clause 26 or 27, further comprising: a computing device of a user, the computing device comprising a user interface configured to display the at least one control instruction.

Clause 29: The system of any of clauses 26-28, further comprising: a measurement device configured to take at least one color measurement of the first coated substrate; and a second model based on experimental color to thickness data and to which the at least one color measurement is input, wherein the second model is programmed or configured to generate the actual coating profile based on the at least one color measurement.

Clause 30: The system of any of clauses 26-29, wherein the at least one applicator comprises a vacuum coating applicator.

Clause 31: The system of clause 30, wherein the vacuum coating applicator comprises at least one gas inlet through which at least one reactive or non-reactive gas is flowed to deposit the at least one coating layer on the surface, wherein the at least one control instruction comprises a control instruction for adjusting a flow rate of the gas through the at least one gas inlet for depositing a coating layer on the second substrate according to the target coating profile.

Clause 32: The system of clause 30 or 31, wherein the vacuum coating applicator comprises a magnet bar arranged at a height above the surface to deposit the at least one coating layer on the surface, wherein the at least one control instruction comprises a control instruction for adjusting the height of the magnet bar above the surface for depositing a coating layer on the second substrate according to the target coating profile.

Clause 33: The system clause 37, wherein the magnet bar comprises a plurality of nodes configured to adjust a height of a section of the magnet bar above the surface, wherein the at least one control instruction comprises a control instruction for only a subset of the plurality of nodes to adjust the height of a corresponding section of the magnet bar above the surface for depositing a coating layer on the second substrate according to the target coating profile.

Clause 34: The system of any of clauses 26-33, further comprising: a scanner configured to identify the first coated substrate by scanning an identifier associated with the first coated substrate.

Clause 35: The system of any of clauses 26-34, wherein the first coated substrate comprises the surface over which a coating stack comprising a plurality of coating layers is positioned, wherein the at least one applicator comprises a plurality of applicators, each applicator of the plurality of applicators configured to apply a different layer of the plurality of layers of the coating stack, wherein generating the at least one control instruction comprises: determining, with the model, at least one applicator of the plurality of applicators requiring adjustment to obtain the target coating profile based on the deviation coating profile; and generating, with the model, the at least one control instruction for at least one component of the at least one applicator of the plurality of applicators requiring adjustment to obtain the target coating profile.

Clause 36: The system of any of clauses 26-35, wherein the system does not comprise a device for directly measuring a thickness of the at least one coating layer.

Clause 37: The system of any of clauses 26-36, wherein the model is programmed or configured to generate the at least one control instruction in response to determining that at least a portion of the deviation coating profile satisfies a threshold.

Clause 38: The system of any of clauses 27-37, wherein the adjusted at least one component is configured to apply at least one second coating layer to a surface of the second substrate according to the target coating profile.

Clause 39: The system of any of clauses 26-38, wherein the at least one applicator comprises a magnetron sputtering vapor deposition (MSVD) applicator.

Clause 40: The system of any of clauses 26-39, wherein the first coated substrate comprises the surface over which a coating stack comprising a plurality of coating layers is positioned, wherein inputting the deviation coating profile into the model comprises inputting coating profile data associated with a first layer of the plurality of layers and a second layer of the plurality of layers, wherein the at least one control instruction for adjusting the at least one component of the at least one applicator is generated to cause the at least one applicator to apply a first layer of a plurality of layers on the second substrate based on the coating profile data associated with the first layer of the plurality of layers and the second layer of the plurality of layers.

Clause 41: The system of any of clauses 26-40, wherein determining the actual coating profile for the first coated substrate comprises the at least one processor determining a thickness of a first layer of the at least one coating layer, the determined thickness of the first layer of the at least one coating layer different from a thickness for the first layer of the at least one coating layer from the target coating profile, wherein the at least one control instruction for adjusting the at least one component of the at least one applicator is generated to cause the at least one applicator to apply a first layer of at least one coating layer on the second substrate at a different thickness compared to the determined thickness of the first layer of the at least one coating layer from the first coated substrate.

Clause 42: The system of any of clauses 26-41, wherein the first coated substrate comprises a post-tempered substrate having the actual coating profile formed by heating a pre-tempered first substrate having a pre-tempered coating profile, wherein generating the at least one control instruction comprises the model: receiving the input comprising the deviation coating profile; analyzing experimental coating control data comprising a plurality of historical pre-tempered coating profiles; determining a first historical pre-tempered coating profile from the plurality of historical pre-tempered coating profiles; and generating the at least one control instruction for adjusting the at least one component of the at least one applicator to cause the at least one applicator to apply the first historical pre-tempered coating profile to a pre-tempered second substrate.

Clause 43: The system of any of clauses 26-42, the at least one processor further programmed or configured to determine, with the model, that the at least one component of the at least one applicator is malfunctioning or satisfies a limit based on the deviation coating profile, wherein the at least one component of the at least one applicator is maintenanced based on the determination that the at least one component of the at least one applicator is malfunctioning or satisfies a limit.

Clause 44: The system of clause 43, the at least one processor further programmed or configured to: in response to determining that the at least one component of the at least one applicator is malfunctioning or satisfies a limit based on the deviation coating profile, automatically update the model based on the malfunctioning or satisfaction of the limit by generating a control instruction that distributes an adjustment to a remainder of components of the at least one applicator.

Clause 45: The system of any of clauses 26-44, wherein the first coated substrate comprises a post-tempered substrate having the actual coating profile formed by heating a pre-tempered first substrate having a pre-tempered coating profile, wherein generating the at least one control instruction comprises the model: receiving the input comprising the deviation coating profile and the pre-tempered coating profile, the deviation coating profile comparing the target coating profile of the post-tempered substrate to the actual coating profile; comparing the pre-tempered coating profile to the actual coating profile; and generating the at least one control instruction for adjusting the at least one component of the at least one applicator based on the comparison of the pre-tempered coating profile to the actual coating profile.

### BRIEF DESCRIPTION OF THE DRAWINGS

The disclosure will be described with reference to the following drawing figures wherein like reference numbers identify like parts throughout.

FIG. 1 shows a schematic diagram of a coated substrate, according to some aspects of the disclosure;

FIG. 2 shows a schematic diagram of a system for automatically controlling a component of a coating applicator, according to some aspects of the disclosure;

FIG. 3 shows a schematic diagram of a control system, according to some aspects of the disclosure;

FIGS. 4A-4B show schematic diagrams of an adjustable magnet bar coating applicator, according to some aspects of the disclosure;

FIG. 5 shows a schematic diagram of a trim gas coating applicator, according to some aspects of the disclosure;

FIG. 6 shows a step diagram of a process for automatically controlling a component of a coating applicator, according to some aspects of the disclosure; and

FIG. 7 shows a schematic diagram of example components of a device used in connection with some aspects of the disclosure.

### DETAILED DESCRIPTION

As used herein, spatial or directional terms, such as “left”, “right”, “inner”, “outer”, “above”, “below”, and the like, relate to the disclosure as it is shown in the drawing figures. However, it is to be understood that the disclosure can assume various alternative orientations and, accordingly, such terms are not to be considered as limiting. Further, as used herein, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims may vary depending upon the desired properties sought to be obtained by the present disclosure. At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 5.5 to 10, and the like. “A” or “an” refers to one or more.

Further, as used herein, the terms “formed over”, “deposited over”, “arranged over”, or “provided over” mean formed, deposited, arranged, or provided on but not necessarily in contact with the surface. For example, a coating layer “arranged over” a substrate does not preclude the presence of one or more other coating layers or films of the same or different composition located between the formed coating layer and the substrate.

As used herein, the terms “communication” and “communicate” may refer to the reception, receipt, transmission, transfer, provision, and/or the like of information (e.g., data, signals, messages, instructions, commands, and/or the like). For one unit (e.g., a device, a system, a component of a device or system, combinations thereof, and/or the like) to be in communication with another unit means that the one unit is able to directly or indirectly receive information from and/or send (e.g., transmit) information to the other unit. This may refer to a direct or indirect connection that is wired and/or wireless in nature. Additionally, two units may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit (e.g., a third unit located between the first unit and the second unit) processes information received from the first unit and transmits the processed information to the second unit. In some non-limiting embodiments or aspects, a message may refer to a network packet (e.g., a data packet and/or the like) that includes data.

Additionally, all documents, such as, but not limited to, issued patents and patent applications, referred to herein are to be considered to be “incorporated by reference” in their entirety.

The disclosure relates to a computer-implemented method for automatically controlling a component of a coating applicator, comprising: identifying, with at least one processor, a first coated substrate comprising a substrate comprising a surface over which at least one coating layer is positioned, the at least one coating layer positioned over the surface using at least one applicator; in response to identifying the first coated substrate, determining, with at least one processor, a target coating profile corresponding to the first coated substrate; determining, with at least one processor, an actual coating profile for the first coated substrate; generating, with at least one processor, a deviation coating profile for the first coated substrate by comparing the target coating profile to the actual coating profile; inputting, with at least one processor, the deviation coating profile into a model based on experimental coating control data; and generating, with the model, at least one control instruction for adjusting at least one component of the at least one applicator based on the deviation coating profile prior to coating a second substrate according to the target coating profile.

The disclosure also relates to a system for automatically controlling a component of a coating applicator, comprising: at least one applicator configured to prepare a first coated substrate comprising a substrate comprising a surface over which at least one coating layer is positioned; and a control system comprising at least one processor programmed or configured to: identify the first coated substrate; in response to identifying the first coated substrate, determine a target coating profile corresponding to the first coated substrate; determine an actual coating profile for the first coated substrate; generate a deviation coating profile for the first coated substrate by comparing the target coating profile to the actual coating profile; input the deviation coating profile into a model based on experimental coating control data; and generate, with the model, at least one control instruction for adjusting at least one component of the at least one applicator based on the deviation coating profile prior to coating a second substrate according to the target coating profile.

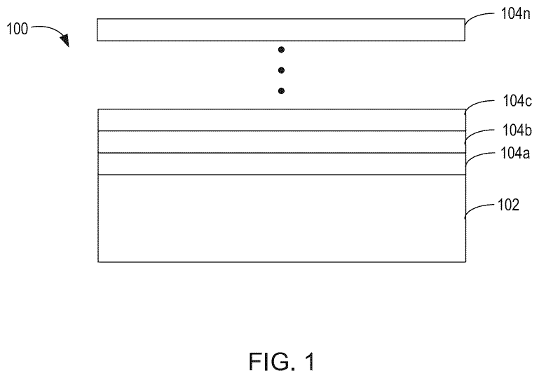

Referring to FIG. 1, the method and system for automatically controlling a component of a coating applicator may be used for preparing a coated substrate 100. The coated substrate 100 may comprise a substrate 102 having a surface coated with at least one coating layer 104a-104n. The coated substrate 100 may comprise the substrate 102 having a single coating layer 104a thereover. The coated substrate 100 may comprise the substrate 102 having a coating stack thereover comprising a plurality of coating layers 104a-104n (e.g., a multi-layer coating).

The material of the substrate 102 is not particularly limited and may include, for example, glass, plastic, metal, ceramic, and/or any combination thereof. The substrate 102 may comprise glass.

Non-limiting examples of suitable plastic materials include acrylic polymers, such as as polyacrylates; polyalkylmethacrylates, such polymethylmethacrylates, polyethylmethacrylates, polypropylmethacrylates, and the like; polyurethanes; polycarbonates; polyalkylterephthalates, such as polyethyleneterephthalate (PET), polypropyleneterephthalates, polybutyleneterephthalates, and the like; polysiloxane-containing polymers; or copolymers of any monomers for preparing these, or any mixtures thereof.

Non-limiting examples of suitable glass materials include conventional soda-lime-silicate glass, borosilicate glass, or leaded glass. The glass can be clear glass. By “clear glass” is meant non-tinted or non-colored glass. Alternatively, the glass can be tinted or otherwise colored glass. The glass can be annealed or heat-treated glass. As used herein, the term “heat treated” means tempered or at least partially tempered. The glass can be of any type, such as conventional float glass, and can be of any composition having any optical properties, e.g., any value of visible transmission, ultraviolet transmission, infrared transmission, and/or total solar energy transmission. By “float glass” is meant glass formed by a conventional float process in which molten glass is deposited onto a molten metal bath and controllably cooled to form a float glass ribbon. Examples of float glass processes are disclosed in U.S. Pat. Nos. 4,466,562 and 4,671,155. The glass materials may comprise a low iron glass, such as a glass having a total iron Fe₂O₃ in the range of greater than 0.00 to 0.10 wt. % or less than 0.02 wt. %. The low iron glass may be less green and have a high visible light transmittance.

The material of the coating layers 104a-104n is not particularly limited and may include, for example dielectric layers, such as zinc oxide, zinc stannate, tin oxide, silicon nitride, titanium oxide, hafnium oxide, zirconium oxide, niobium oxide, bismuth oxide, lead oxide, indium oxide, silicon oxide, gallium oxide, vanadium oxide, and the like; metallic layers, such as silver, gold, copper, aluminum, titanium, and the like; or any combination thereof. The coating layers 104a-104n may have the same or different thicknesses and may be arranged in any suitable order, as specified by the specifications of the coated substrate 100.

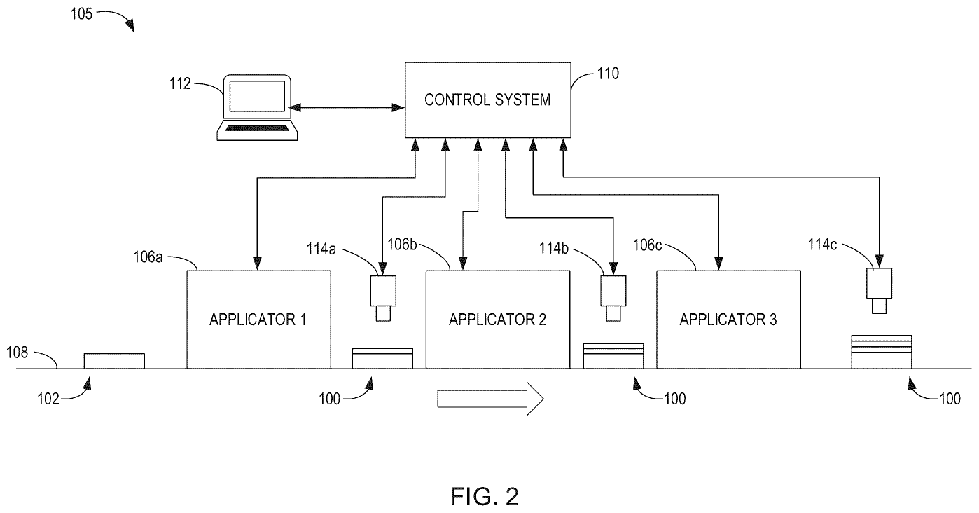

Referring to FIG. 2, a system 105 is shown for automatically controlling a component of a coating applicator, according to some aspects of the disclosure. The system 105 may comprise at least one applicator 106a-106c for applying at least one coating layer. The system 105 of FIG. 2 shows a plurality of coating applicators 106a-106c in series, but it will be appreciated that the system 105 may have any number or arrangement of coating applicators 106a-106c and, in some non-limiting embodiments or aspects, may have a single coating applicator 106a. Each coating applicator 106a-106c may comprise an adjustor configured to automatically adjust a component of the coating applicator 106a-106c, such as based on a control instruction from control system 110.

The coating applicator 106a-106c may be any suitable coating applicator for applying a coating layer to a substrate. Non-limiting examples of the coating applicator 106a-106c may comprise at least one of a vacuum coating applicator; a sputter coating applicator, such as a magnetron sputtering vapor deposition (MSVD) applicator, an ion beam sputtering (IBS) applicator, and the like.

In the non-limiting example of the system 105 of FIG. 2, three coating applicators 106a-106c are included in series with each coating applicator 106a-106c applying a single coating to the substrate 102. The system 105 may include a conveyor 108 for moving the substrate 102 and/or coated substrate 100 through the coating applicators 106a-106c. The conveyor 108 in FIG. 2 moves the substrate 102 and/or coated substrate 100 from left to right. The conveyor 108 can be any suitable device for moving the substrate 102 and/or coated substrate 100 through the system 105.

With continued reference to FIG. 2, the system 105 may comprise the control system 110 for controlling one or more aspect of the system 105. The system 105 may comprise a user device 112 configured to enable a user to interact with and/or control components of the system 105. The user device 112 may be a computing device that may comprise a user interface to display for the user at least one parameter of the system 105. The user device 112 may comprise at least one input component configured to receive input from the user, which input may be used to control at least one component of the system 105.

The system 105 may comprise at least one analyzer 114a-114c. The analyzer 114a-114c may be arranged at any location in the system 105, and in some non-limiting embodiments or aspects may be arranged before and/or after one or more coating applicators 106a-106c. The system 105 may comprise a plurality of analyzers 114a-114c or may comprise a single analyzer 114a. The analyzers 114a-114c may automatically analyze one or more parameters of the system 105 and/or the substrate 102 and/or coated substrate 100, such as by automatically taking one or more measurements or making one or more readings.

The analyzers 114a-114c may automatically analyze any suitable parameters of the system.

For example, the analyzers 114a-114c may analyze one or more parameter of the applicators 106a-106c, such as a temperature condition in the applicators 106a-106c, an amount of coating material remaining in the applicators 106a-106c, an application rate of coating material, position of the applicators 106a-106c in the system 105, and/or the like.

The analyzers 114a-114c may analyze one or more parameters associated with the conveyor 108, such as conveyor speed and/or location of substrates 102 and/or coated substrates 100 on the conveyor 108, and/or the like.

The analyzers 114a-114c may analyze one or more parameters associated with the substrate 102, such as dimensions of the substrate 102, material of the substrate, whether the substrate 102 has been coated or not, the location of the substrate 102, the unique identity of the substrate 102, and/or the like. For example, the unique identity of the substrate 102 may be identified based on the location of the substrate 102 in the system 105 and/or by the analyzers 114a-114c (e.g., a scanner) scanning a unique identifier (e.g., a barcode, QR code, or other type of unique identifier) arranged on the substrate 102 or associated with the substrate 102.

The analyzers 114a-114c may analyze one or more parameters associated with the coated substrate 100. The analyzers 114a-114c may analyze the coated substrate 100 after all coating layers have been applied and/or may analyze the coated substrate 100 between coating layer applications (e.g., after application of a first coating layer but before application of the subsequent second coating layer). The analyzers 114a-114c may analyze, for example, thickness or thickness profile of one or more coating layers using an indirect measurement technique (e.g., ellipsometry, interferometry, Eddy current method, and the like), color or color profile (e.g., spectrometer, spectrophotometer, colorimeter, and the like) of the coating layer and/or coated substrate 100, material of the coating layer(s) (e.g., as predetermined for the coated substrate 100, determined using x-ray spectroscopy, and the like), and the like.

The analyzers 114a-114c may take a plurality of different measurements and/or readings described above and may be a single measurement device configured to take all of the measurements or readings or a plurality of different measurement devices configured to take one or more of the of the measurements or readings.

In some non-limiting embodiments or aspects, the system 105 may not comprise a device for directly measuring a thickness of the at least one coating layer. A direct measuring technique may be one that obtains the coating layer thickness through dimensional measuring as opposed to inferring the thickness through other properties. Examples of direct measuring techniques can include cross-sectional transmission electron microscopy, cross-sectional scanning electronic microscopy, atomic force microscopy, profilometry, and the like.

With continued reference to FIG. 2, the control system 110 may communicate with one or more other components of the system 105. For example, the control system 110 may communicate with at least one of the coating applicators 106a-106c, the user device 112, and/or the analyzers 114a-114c.

The control system 110 may receive messages from the coating applicators 106a-106c reporting at least one parameter of the coating applicators 106a-106c and/or providing a control instruction to the control system 110; the coating applicators 106a-106c may receive messages from the control system 110 reporting at least one parameter of another component of the system 105 and/or providing a control instruction to the coating applicators 106a-106c.

The control system 110 may receive messages from the user device 112 comprising an input from the user, which the control system 110 may use to control one or more components of the system 105; the user device 112 may receive messages from the control system 110 to cause the user device 112 to display (on the user interface) at least one message or parameter associated with the system 105 for the user. The at least one message or parameter displayed may comprise at least one control instruction (e.g., the control instruction the control system 110 provided to a component of the system 105) and/or a request for a control instruction or approval of a control instruction.

The control system 110 may receive messages from the analyzers 114a-114c reporting at least one parameter of the analyzers 114a-114c and/or a measurement or reading taken by the analyzers 114a-114c and/or providing a control instruction to the control system 110; the analyzers 114a-114c may receive messages from the control system 110 reporting at least one parameter of another component of the system 105 and/or providing a control instruction to the analyzers 114a-114c (e.g., to take or stop taking readings and/or measurements).

With continued reference to FIG. 2, the system 105 may be used for producing coated substrates 100. In this non-limiting example, the system 105 may comprise 3 coating applicators 106a-106c, 3 analyzers 114a-114c, with an analyzer 114a-114b between each applicator 106a-106c and an analyzer 114c after the third applicator 106c. The system 105 may produce a coated substrate 100 having a three coating layer stack over a surface of the substrate 102. It will be appreciated that the number and arrangement of components of the system 105 shown in FIG. 2 is non-limiting and for illustrative purposes only and that variations to the system 105 shown in FIG. 2 are within the scope of the present disclosure.

In this non-limiting example, the substrate 102 (uncoated) may be moved by the conveyor 108 to the first applicator 106a, which may apply a first coating layer over the surface of the substrate 102 to produce the coated substrate 100. The coated substrate 100 exiting the first applicator 106a may be analyzed by the first analyzer 114a and subsequently moved by the conveyor 108 to the second applicator 106b, which may apply a second coating layer over the first coating layer to produce the coated substrate 100. The coated substrate 100 exiting the second applicator 106b may be analyzed by the second analyzer 114b and subsequently moved by the conveyor 108 to the third applicator 106c, which may apply a third coating layer over the second coating layer to produce the coated substrate 100. The coated substrate 100 exiting the third applicator 106c may be analyzed by the third analyzer 114c. The coated substrate 100 prepared by the system 105 of FIG. 2 may have been prepared according to a target coating profile predetermined for the substrate 102. The coated substrate 100 prepared by the system 105 may be analyzed by the control system 110, and the components of the system 105 (e.g., the applicators 106a-106c) may be adjusted thereby prior to preparation of a second coated substrate so that the system 105 produces the second coated substrate having an actual coating profile closer to the target coating profile, which is described in detail hereinafter.

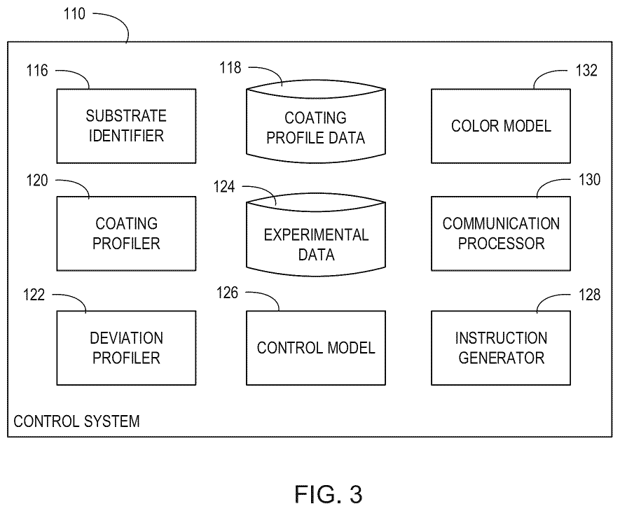

Referring to FIG. 3, the control system 110 is shown according to some aspects of the disclosure. The control system 110 may comprise at least one of a substrate identifier 116, a coating profile data database 118, a coating profiler 120, a deviation profiler 122, an experimental data database 124, a control model 126, an instruction generator 128, a communication processor 130, and/or a color model 132. The components of the control system 110 shown in FIG. 3 may be separate components as shown, or one or more components shown in FIG. 3 may be combined to form a single component, or a single component shown in FIG. 3 may be subdivided into multiple components.

The communication processor 130 may be a component of the control system 110 comprising a processor programmed or configured to communicate with other components of the system 105 from FIG. 2. For example, the communication processor 130 may communicate with at least one of the applicators 106a-106c, the conveyor 108, the user device 112, and/or the analyzers 114a-114c. The communication processor 130 may receive messages from such components and/or the communication processor 130 may transmit messages (e.g. containing control instructions) to such components.

The substrate identifier 116 may be a component of the control system 110 comprising a processor programmed or configured to identify a substrate 102 and/or coated substrate 100 proceeding through the system 105 (see e.g., FIG. 2). The substrate identifier 116 may identify the substrate 102 and/or coated substrate 100 using any suitable protocol.

For example, the substrate 102 and/or coated substrate 100 may comprise a unique identifier physically arranged on the substrate 102 and/or coated substrate 100. The analyzers 114a-114c may read the unique identifier arranged on the substrate 102 and/or coated substrate 100 and transmit a message to the control system 110 that contains the unique identifier read by the analyzers 114a-114c. In some non-limiting embodiments or aspects, the unique identifier may comprise a computer-readable unique identifier, and analyzers 114a-114c may comprise scanners configured to read the computer-readable unique identifier. Based on the unique identifier, the substrate identifier 116 may identify the substrate 102 and/or coated substrate 100. The substrate identifier 116 may comprise a database that stores the unique identifier in association with the identity of the substrate 102 and/or coated substrate 100, such that in response to receiving the unique identifier, the substrate identifier 116 can identify the substrate 102 and/or coated substrate 100.

As another non-limiting example, the substrate 102 and/or coated substrate 100 may not comprise a unique identifier physically arranged on the substrate 102 and/or coated substrate 100, but the substrate 102 and/or coated substrate 100 may have a digitally generated virtual identifier associated therewith and tracked by the control system 110 as the substrate 102 and/or coated substrate 100 proceeds through the system 105. The virtual identifier may be stored in the database of the substrate identifier 116 in association with the identity of the substrate 102 and/or coated substrate 100. The substrate identifier 116 may track the substrate 102 and/or coated substrate 100 through the system 105 using the analyzers 114a-114c (e.g., comprising a photoelectric sensor, a (video) camera, and the like). The substrate identifier 116 may track the substrate 102 and/or coated substrate 100 through the system 105 based on the speed through which the substrate 102 and/or coated substrate 100 moves (e.g., based on speed of the conveyor 108, speed of the coating applicators 106a-106c, and the like). The substrate identifier 116 may identify a particular substrate 102 and/or coated substrate 100 located in the system 105 by determining the virtual identifier thereof based on the foregoing data (e.g., sensor data, speed data, etc.), and based on the virtual identifier, identify the specific substrate 102 and/or coated substrate 100 based on the association in the database between the virtual identifier and the substrate 102 and/or coated substrate 100.

As another non-limiting example, the substrate 102 and/or coated substrate 100 may not comprise a unique identifier physically arranged on the substrate 102 and/or coated substrate 100, but the substrate 102 and/or coated substrate 100 may be determined based on at least one parameter associated with the substrate 102 and/or coated substrate 100. For example, the database of the substrate identifier 116 may store a data packet comprising at least one of coating information and/or dimension information, and such information may be store in association with the substrate 102 and/or coated substrate 100. The analyzer 114a-114c may detect coating information and/or dimension information associated with a substrate 102 and/or coated substrate 100 in the system 105 and transmit a message to the control system 110 containing such information. Based on the coating information and/or dimension information in the message, the substrate identifier 116 may determine the specific substrate 102 and/or coated substrate 100 based on the associations in the database.

While several non-limiting examples of the substrate identifier 116 identifying the substrate 102 and/or coated substrate 100 have been shown and described, it will be appreciated that any other technique of identifying the substrate 102 and/or coated substrate 100 may be employed according to the present disclosure.

The coating profile data database 118 may be a component of the control system 110 programmed or configured to determine a target coating profile associated with the identified coated substrate 100. In response to identifying the coated substrate 100 (e.g., with the substrate identifier 116), the coating profile data database 118 may determine the target coating profile associated with the identified coated substrate 100. The coating profile data database 118 may comprise a database that stores an association between the coated substrate 100 (e.g., using an identifier thereof) and the target coating profile of the coated substrate. The identifier of the coated substrate 100 may identify the specific coated substrate 100 and/or may identify a type of coated substrate 100 to which the specific coated substrate 100 belongs. The target coating profile may be a predetermined coating profile selected by the system 105 or users thereof to which the system 105 is targeting to apply the coating layer(s) to the substrate 100. The target coating profile may comprise at least one of, the target number of coating layers, the target materials of the coating layers, the target arrangement of the coating layers, the target thickness of the coating layers, and the like. The target coating profile may provide a target coating thickness for at least one layer of the coated substrate 100 relative to a position on the surface. The target coating profile may be associated in the coating profile data database 118 with a specific coated substrate 100 and/or with a type of coated substrate 100. Therefore, based on the identified coated substrate 100, the coating profile data database 118 can determine the target coating profile intended to be applied thereto by the system 105.

The coating profiler 120 may be a component of the control system 110 comprising a processor programmed or configured to determine an actual coating profile for the identified coated substrate 100. The actual coating profile may correspond to the actual coating parameters applied to the coated substrate 100, which may be different from the target (intended) coating profile. The actual coating profile may comprise at least one of, the actual number of coating layers, the actual materials of the coating layers, the actual arrangement of the coating layers, the actual thickness of the coating layers, and the like. The actual coating profile may provide an actual coating thickness for at least one layer of coated substrate relative to a position on the surface. The coating profiler 120 may determine the actual coating profile of the coated substrate 100 based on receiving a message from the analyzers 114a-114c comprising measurements and/or readings of the coated substrate taken thereby. The measurements and/or readings may comprise any of the indirect thickness measurements previously described. The measurements and/or readings may comprise at least one measurement or reading corresponding to a color of the coating layer and/or coated substrate 100, a material of the coating layer(s), and the like. Based on the received measurements or readings, the coating profiler 120 may generate the actual coating profile of the coated substrate 100.

In some non-limiting embodiments or aspects, determining the actual coating profile for the coated substrate 100 may include determining a thickness of a first layer, the determined thickness of the first layer different from a thickness for the first layer from the target coating profile. The at least one control instruction for adjusting the component of the applicators 106a-106c may be generated to cause the applicators 106a-106c to apply the same (e.g., compositionally) first layer on a second substrate at a different thickness compared to the determined thickness of the first layer from the coated substrate 100.

In some non-limiting embodiments or aspects, the coated substrate 100 may include a post-tempered (or otherwise heat treated) substrate having the actual coating profile formed by heating a pre-tempered substrate having a pre-tempered coating profile. Generating the at least one control instruction may comprise the control model 126: receiving the input comprising the deviation coating profile; analyzing experimental coating control data comprising a plurality of historical pre-tempered coating profiles (e.g., stored in experimental data database 124); determining a first historical pre-tempered coating profile from the plurality of historical pre-tempered coating profiles; and generating the at least one control instruction for adjusting the component of the applicators 106a-106c to cause the applicators 106a-106c to apply the first historical pre-tempered coating profile to a pre-tempered second substrate. In this way, the effect of tempering on coating profiles may be considered in the generation of the control instruction.

In some non-limiting embodiments or aspects, the coated substrate 100 may include a post-tempered (or otherwise heat treated) substrate having the actual coating profile formed by heating a pre-tempered substrate having a pre-tempered coating profile. Generating the at least one control instruction may comprise the control model 126: receiving the input comprising the deviation coating profile and the pre-tempered coating profile, the deviation coating profile comparing the target coating profile of the post-tempered substrate to the actual coating profile; comparing the pre-tempered coating profile to the actual coating profile; and generating the control instruction for adjusting the component of the applicators 106a-106c based on the comparison of the pre-tempered coating profile to the actual coating profile.

The deviation profiler 122 may be a component of the control system 110 comprising a processor programmed or configured to generate a deviation coating profile for the coated substrate. The deviation coating profile may be generated by comparing the target coating profile (e.g., from the coating profile data database 118) to the actual coating profile (e.g., from the coating profiler 120) to determine a difference between the target coating profile and the actual coating profile. The deviation coating profile may comprise at least one of, the difference in the number of coating layers, the materials of the coating layers, the arrangement of the coating layers, the thickness of the coating layers, the thickness gradient of the coating layers, and the like between the target coating profile and the actual coating profile.

In some non-limiting embodiments or aspects, the deviation profiler 122 may generate the deviation coating profile after a plurality of or all coating layers of the coated substrate 100 have been applied and/or based on data taken by the analyzer 114a-114c after a plurality of or all coating layers of the coated substrate 100 have been applied. In some non-limiting embodiments or aspects, the deviation profiler 122 may generate the deviation coating profile after a first layer of the coating stack of the coated substrate 100 is positioned on the surface but before a second layer of the coating stack is positioned over the first layer (e.g., prior to completion of the coated substrate 100) and/or based on data taken by the analyzer 114a-114c after a first layer of the coating stack of the coated substrate 100 is positioned on the surface but before a second layer of the coating stack is positioned over the first layer.

The experimental data database 124 may be a component of the control system 110 programmed or configured to store historical experimental data. The historical experimental data may comprise data associated with previous substrates coated with one or more coating layers. For example, the historical experimental data may comprise target coating profile data and/or actual coating profile data associated with previously prepared coated substrates. The historical experimental data may comprise data associated with how adjusting a component of the system 105 (see e.g., from FIG. 2) affected the actual coating profile of coated substrates coated after the adjustment (compared to before the adjustment), such that the impact that adjusting a particular component or combination of components of the system 105 can be quantified. The historical experimental data may comprise data associated with color data of historical coated substrates and/or coating layers thereof and how the color data corresponded to at least one of a coating thickness, coating material, and/or coating layer arrangement. Such historical experimental data may quantify how a color reading from the analyzers 114a-114c for a coated substrate corresponds to at least one of a coating thickness, coating material, and/or coating layer arrangement for the coated substrate. These examples of historical experimental data are non-limiting and any other data associated with previously prepared coated substrates may be stored in the experimental data database 124.

The control model 126 may be a component of the control system 110 comprising a processor programmed or configured to generate at least one control instruction for adjusting a component of the system 105 (e.g., at least one coating applicator 106a-106c thereof) prior to coating a second substrate according to the target coating profile. The control model 126 may comprise any suitable computer-based model. For example, the control model 126 may comprise a machine-learning model, such as an artificial neural network trained on at least a portion of the data from the experimental data database 124. The training data may comprise at least a portion of the historical experimental data associated with how adjusting a component of the system 105 (e.g., at least one coating applicator 106a-106c thereof) affected the actual coating profile of coated substrates coated after the adjustment (compared to before the adjustment) [also referred to herein as experimental coating control data]. For example, the control model 126 may comprise a statistics-based and/or physics-based model generated using data from the experimental data database 124 (e.g., the historical experimental data associated with how adjusting a component of the system 105 (e.g., at least one coating applicator 106a-106c thereof) affected the actual coating profile of coated substrates coated after the adjustment (compared to before the adjustment).

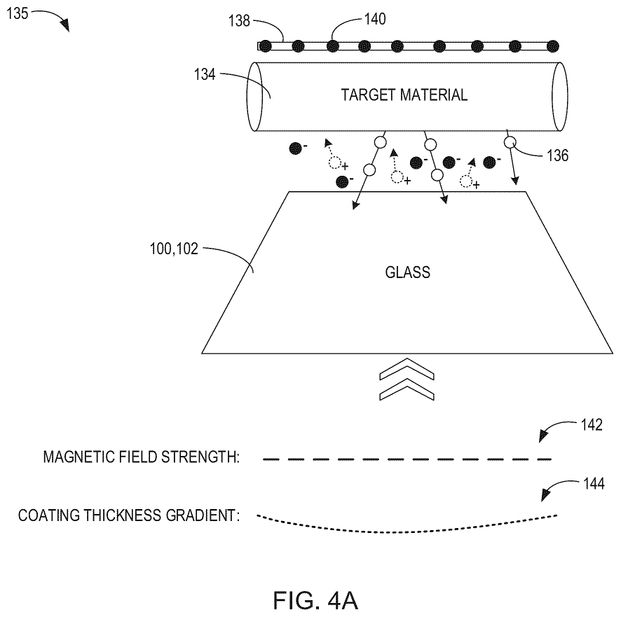

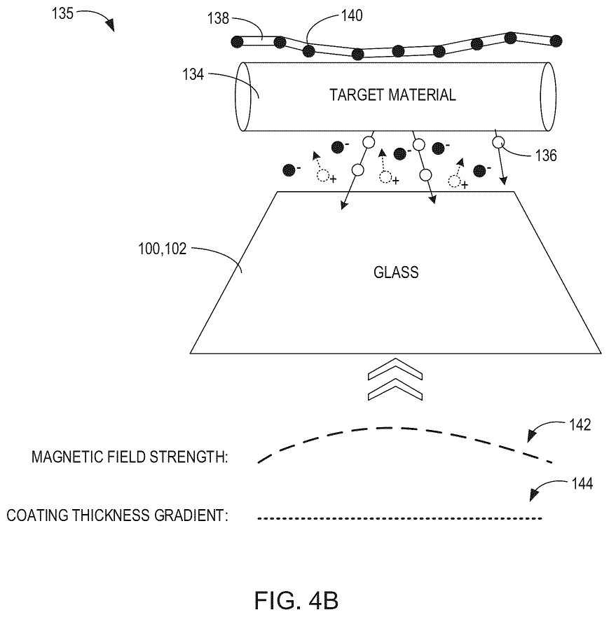

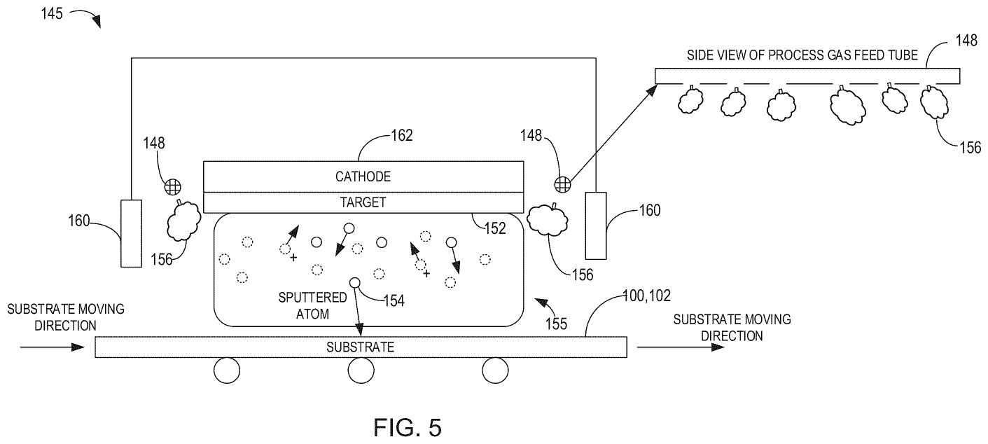

The deviation coating profile (e.g., from the deviation profiler 122) may be input to the control model 126. In response to receiving the input, the control model 126 may automatically generate at least one control instruction for adjusting a component of the system 105 (e.g., the applicators 106a-106c) prior to coating a second substrate according to the target coating profile. The control instruction may comprise an instruction to cause an adjustor of the at least one of the applicators 106a-106c to adjust at least one parameter of the applicators 106a-106c (e.g., as described hereinafter in connection with FIGS. 4A-5). The control instruction may comprise an instruction to the conveyor 108 to adjust a parameter thereof (e.g., a conveyor speed thereof, and the like). The control instruction may comprise an instruction to at least one of the analyzers 114a-114c to adjust a parameter thereof (e.g., a frequency and/or timing for taking a measurement or reading, and the like). The control instruction may comprise an instruction to the user device 112 to cause the user to effect an adjustment to the system 105 or to request user input for adjusting the system 105.

In some non-limiting embodiments or aspects, inputting the deviation coating profile into the control model 126 may include inputting coating profile data associated with a first layer of the plurality of layers and a second layer of the plurality of layers of the coated substrate 100. The control instruction for adjusting a component of the applicators 106a-106c may be generated to cause the applicators 106a-106c to apply a first layer of a plurality of layers on the next substrate based on the coating profile data associated with the first layer of the plurality of layers and the second layer of the plurality of layers.

In some non-limiting embodiments or aspects, the control model 126 may automatically generate a control instruction after the production of each coated substrate 100 so that adjustments can be made to the system 105 so that the next coated substrate produced has an actual coating profile closer to the target coating profile (a reduced deviation coating profile). In some non-limiting embodiments or aspects, the control model 126 may automatically generate a control instructions periodically (e.g., after a predetermined time period, after a predetermined number of coated substrates have been produced, and the like) so that adjustments can be made to the system 105 so that the next coated substrate produced has an actual coating profile closer to the target coating profile (a reduced deviation coating profile) for the next coated substrate produced. When multiple coated substrates 100 have been produced between executions of the control model 126, the deviation profiles input to the control model 126 may include all of or a subset or a combination of the deviation profiles of the multiple coated substrates 100 that have been produced between executions of the control model 126. A combination of deviation profiles may comprise an average, a weighted average, or other statistical function applied to the deviation profiles being input to the control model 126.

In some non-limiting embodiments or aspects, the control model 126 may generate the control instruction in response to determining that at least a portion of the deviation coating profile input to the control model satisfies a threshold. This feature enables the system 105 to only adjust a component thereof when a deviation from the target coating profile satisfies a threshold. The threshold being satisfied may comprise the number of coatings, thickness of coatings, material of coatings, arrangement of coatings, and the like deviating from the target coating profile by more than a predetermined deviation threshold. For example, the threshold may be satisfied by an actual coating thickness deviating by more than a predetermined amount, percent, or the like from the target coating thickness.

In some non-limiting embodiments or aspects, the coated substrate 100 comprises a plurality of coating layers applied by a plurality of applicators 106a-106c (e.g., the first through third applicators 106a-106c), with each applicator 106a-106c applying a different coating layer of the coating stack applied thereto (see e.g., FIG. 2). In generating the control instruction, the control model 126 may determine at least one applicator (e.g., the first coating applicator 106a) of the plurality of applicators 106a-106c requiring adjustment to obtain the target coating profile based on the deviation coating profile. Based on the determination, the control model 126 may generate at least one control instruction for the first applicator 106a, which may be transmitted to the first applicator 106a to cause adjustment thereof to obtain the target coating profile. In some non-limiting embodiments or aspects, a plurality of applicators 106a-106c may require adjustment.

In some non-limiting embodiments or aspects, the system 105 may automatically identify at least one parameter of the at least one applicator 106a-106c and/or a parameter of a coating process for coating the substrate 102. For example, the at least one parameter may comprise a parameter of the applicators 106a-106c, such as an aging condition of the applicators 106a-106c and/or at least one component thereof. For example, the at least one parameter may comprise a glass quality parameter (e.g., a breakage parameter, a present periodic gas composition change parameter, and the like). The at least one parameter of the at least one applicator 106a-106c and/or a parameter of a coating process may be input to the control model 126, and the control instruction generated by the control model 126 may be based at least partially on the parameter input to the control model 126.

In some non-limiting embodiments or aspects, the control model 126 may determine that a component of the applicators 106a-106c is malfunctioning or satisfies a limit based on the deviation coating profile. A malfunctioning component may refer to a component that is at least partially broken and/or operating in a manner different from the intended operation of the component. A component that satisfies a limit may refer to a component that is operating at an actual and/or theoretical limit such that allowing the component beyond the limit is not possible and/or would be expected to cause the component to malfunction. For example, a component that alters gas flow that is closed such that gas flow is 0 may satisfy a limit because the component cannot be more closed since it already fully prevents the flow of gas. For example, a component made of a material having a theoretical stress/strain curve and/or modulus of elasticity and/or other relevant material property may have a theoretical property limit of the material that, if exceed, would be expected to cause the material to fail.

In response to determining that the component of the applicators 106a-106c is malfunctioning or satisfies a limit based on the deviation coating profile, the component may be maintenanced. Maintenancing the component may be completed in any suitable manner. For example, maintenancing the component may comprise replacing the component with a different (e.g., new) component. Maintenancing the component may comprise fixing the component. The component may be maintenanced by an operator or may be automatically maintenanced (e.g., by the adjustor). A control instruction may be generated by the control model 126 to notify the operator that the component should be maintenanced. A control instruction may be generated by the control model 126 to cause the component to be automatically maintenanced.

In response to determining that the component of the applicators 106a-106c is malfunctioning or satisfies a limit based on the deviation coating profile, the control model 126 may automatically be updated based on the malfunctioning or satisfaction of the limit. The control model 126 may be updated by generating a control instruction that distributes an adjustment to a remainder of components of the applicator(s) 106a-106c (e.g., to compensate for the malfunctioning component).

The instruction generator 128 may be a component of the control system 110 comprising a processor programmed or configured to generate the message comprising the control instruction generated by control model 126. The communication processor 130 may communicate the message comprising the control instruction to one or more components of the system 105 (e.g., the coating applicators 106a-106c) to cause the components to execute the adjustment specified by the control instruction.

In some non-limiting embodiments or aspects, the communication processor 130 may communicate the message containing the control instruction directly to the components of the system 105 to which the control instructions require adjustment. In some non-limiting embodiments or aspects, the communication processor 130 may first communicate the message containing the control instruction directly to the user device 112 to display the proposed control instruction to the user. The user may approve or decline the control instruction by providing a user input to the user device 112. In response to the user approving the control instruction, the communication processor 130 may communicate the message containing the control instruction to the components of the system 105 to which the control instructions require adjustment.

In some non-limiting embodiments or aspects, in response to transmission of the message comprising the control instruction, at least one component of the system 105 may be automatically adjusted prior to preparation of a second coated substrate having the same target coating profile. For example, in response to transmission of the message comprising the control instruction, at least a component of at least one of the applicators 106a-106c may be automatically adjusted prior to preparation of a second coated substrate having the same target coating profile. After adjustment of the at least one component, the system 105 may apply one or more coating layers using the adjusted at least one component to a surface of a second substrate according to the target coating profile. Based on the adjustment made to the system, the deviation coating profile of this second coated substrate may be reduced compared to the deviation coating profile of the first coated substrate (e.g., the actual coating profile thereof be closer to the target coating profile).

The color model 132 may be a component of the control system 110 comprising a processor programmed or configured to contribute to generating the actual coating profile of the coated substrate 100. In some non-limiting embodiments or aspects, the actual coating profile may be generated based at least in part based on color data of the coated substrate 100 (as a whole or of one or more coating layers thereof). The analyzers 114a-114c (e.g., spectrometer, spectrophotometer, colorimeter, and the like) may take a color reading and/or measurement at one or more locations in the system 105 producing the coated substrate 100. The color reading and/or measurement may be transmitted from the analyzer 114a-114c to the control system 110 and input to the color model 132.

The color model 132 may comprise any suitable computer-based model. For example, the color model 132 may comprise a machine-learning model, such as an artificial neural network trained on at least a portion of the data from the experimental data database 124. The training data may comprise at least a portion of the historical experimental data associated with color data of historical coated substrates and/or coating layers thereof and how the color data corresponded to at least one of a coating thickness, coating material, and/or coating layer arrangement [also referred to herein as historical experimental color data, which includes experimental color to thickness data]. For example, the color model 132 may comprise a statistics-based and/or physics-based model generated using data from the experimental data database 124 (e.g., the historical experimental color data).

For the color model 132 to contribute to generating the actual coating profile of the coated substrate 100, at least one of the analyzers 114a-114c (e.g., a measurement device) may take at least one color measurement of the coated substrate (e.g., in its partially completed and/or completed form), which may be transmitted to the control system 110. The color measurement may be input to the color model 132. The color model 132 may generate the actual coating profile based at least in part on the input color measurement.

Referring to FIGS. 4A-4B, an adjustable magnet bar coating applicator 135 (e.g., a vacuum coating applicator) is shown, according to some aspects of the disclosure. FIG. 4A shows the adjustable magnet bar coating applicator 135 in a first position, and FIG. 4B shows the adjustable magnet bar coating applicator 135 in a second position.

In FIGS. 4A-4B, a substrate 102 of glass is coated to form a coated substrate 100. The adjustable magnet bar coating applicator 135 may deposit at least one coating layer to the surface of the substrate 102. The glass is moved beneath the adjustable magnet bar coating applicator 135 to coat the glass. The adjustable magnet bar coating applicator 135 may comprise a target material holder 134 holding a target material 136, the target material 136 used to coat the glass. The adjustable magnet bar coating applicator 135 may comprise a remotely adjustable magnet bar 138 comprising a plurality of nodes 140. The nodes 140 of the magnet bar 138 may be moved up or down to adjust the distance of the magnet bar 138 from the target surface of the glass. The nodes 140 of the magnet bar 138 may be adjusted in response to receiving a control instruction from the control system 110 (see e.g., FIGS. 2-3), so that the coating layer deposited on the subsequent substrate is according to the target coating profile. The control instruction may cause all nodes 140 of the magnet bar 138 to be adjusted in height or may cause only a subset of the nodes 140 to be adjusted in height.

As shown in FIG. 4A, the nodes 140 may all be the same distance from the target surface, or as shown in FIG. 4B, the nodes 140 of the magnet bar 138 may be different distances from the target surface. Adjusting the height of the nodes 140 may fine tune the local deposition of the target material 136 onto the glass to improve uniformity control of the coating layer thickness (e.g., adjusting components so that a uniform (or more uniform) coating layer is applied as opposed to a non-uniform coating layer). Therefore, the height of the nodes 140 may be individually adjusted to adjust the height of a section of the nodes 140 of the magnet bar 138.

The target material 136 may be applied to the glass by applying a magnetic field (e.g., by the magnet bar 138) to deposit the target material 136 to the glass. The magnetic field strength 142 generated by the magnetic bar may be adjusted based on the height of the nodes 140 to yield the desired coating thickness gradient 144 (e.g., a coating profile).

For example, the magnet bar 138 having the nodes 140 all at a same height from the glass may exhibit a uniform magnetic field strength 142 across the glass, but may result in a coating thickness gradient 144 thicker at the ends of the glass and thinner in the middle of the glass, as shown in the non-limiting example of FIG. 4A. In contrast, adjusting the height of the nodes 140 so that the magnetic field strength 142 exhibited by the magnet bar 138 is stronger in the middle and weaker on the ends may provide for a uniform coating thickness gradient 144, as shown in the non-limiting example of FIG. 4B.

Referring to FIG. 5, a trim gas coating applicator 145 is shown, according to some aspects of the disclosure. The trim gas coating applicator 145 may comprise a process gas feed tube 148 for providing a sputtering gas 156. The trim gas applicator 145 may comprise at least one cathode 162 and at least one anode 160. A target platform 152 containing target material 154 may be arranged, and target material 154 may be used to coat a substrate 102 to form a coated substrate 100. The target platform 152 may be arranged on the cathode 162.

The sputtering gas 156 may be flowed through the process gas feed tube 148 and toward the target platform 152. The sputtering gas 156 may be an inert (e.g., non-reactive) or reactive gas. The control system 110 (see e.g., FIGS. 2-3) can automatically adjust the local flow rate of both types of process gases (e.g., non-reactive and reactive gases at different locations across the substrate 102 and/or coated substrate 100). The sputtering gas 156 may be an inert gas. In another embodiment, the sputtering gas 156 may contain a reactive gas. In reactive sputtering, the deposition rate and deposition mode may be affected and determined by the reactive gas concentration, which is a function of the reactive gas flow rate. Upon the sputtering gas 156 colliding with the target material 154 on the target platform 152, the target material 154 may be ejected through a plasma 155 and toward the substrate 102 to coat the substrate 102.

Parameters of the sputtering gas 156 may be adjusted in response to receiving a control instruction from the control system 110, so that the coating layer deposited on the substrate 102 is according to the target coating profile. For example, the flow rate of the sputtering gas 156 may be adjusted (e.g., increased or decreased) to adjust the deposition of the target material 154 on the substrate 102 in response to receiving the control instruction.

A single process gas feed tube 148 or a plurality of process gas feed tubes 148 may be provided. The control instruction may cause the flow rate of the sputtering gas 156 to be adjusted to all process gas feed tubes 148, or the control instruction may cause the flow rate of the sputtering gas 156 to be adjusted to a subset of the process gas feed tubes 148.

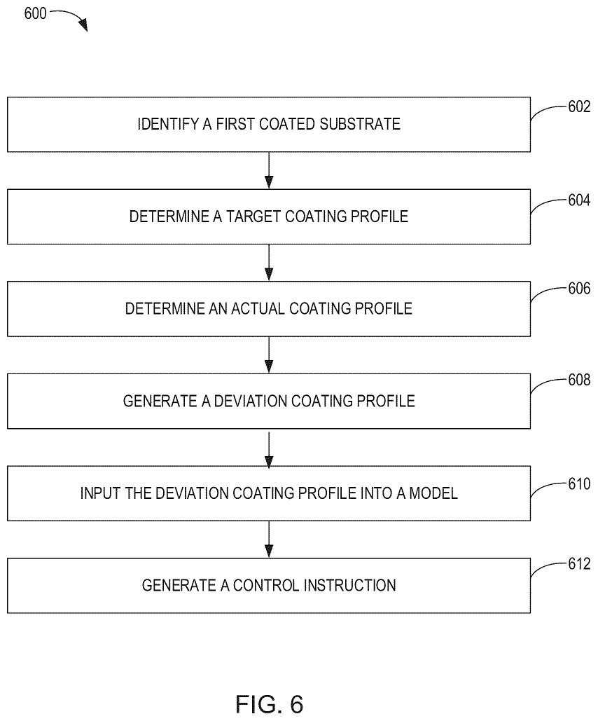

Referring to FIG. 6 (and FIGS. 2-3), a process 600 is shown for automatically controlling a component of a coating applicator, according to some aspects of the disclosure.

At a step 602, the process 600 may include identifying a first coated substrate comprising a substrate comprising a surface over which at least one coating layer is positioned, the at least one coating layer positioned over the surface using at least one applicator 106a-106c. The first coated substrate may be identified based on at least one of the substrate 102 and/or coated substrate 100, data from at least one of the analyzers 114a-114c, and using the substrate identifier 116 of the control system 110.

At a step 604, the process 600 may include, in response to identifying the first coated substrate, determining, with at least one processor, a target coating profile corresponding to the first coated substrate. The target coating profile may be determined based on the identified first coated substrate using the coating profile data database 118 of the control system 110.

At a step 606, the process 600 may include determining, with at least one processor, an actual coating profile for the first coated substrate. The actual coating profile may be determined based on the coated substrate 100, data from at least one of the analyzers 114a-114c and using the coating profiler 120 of the control system 110.

At a step 608, the process 600 may include generating, with at least one processor, a deviation coating profile for the first coated substrate by comparing the target coating profile to the actual coating profile. The deviation coating profile may be generated by the deviation profiler 122 of the control system 110.

At a step 610, the process 600 may include inputting, with at least one processor, the deviation coating profile into a model based on experimental coating control data. The deviation coating profile may be input to the control model 126 of the control system 110.

At a step 612, the process 600 may include generating, with the model, at least one control instruction for adjusting at least one component of the at least one applicator based on the deviation coating profile prior to coating a second substrate according to the target coating profile. The control model 126 may generate the at least one control instruction.

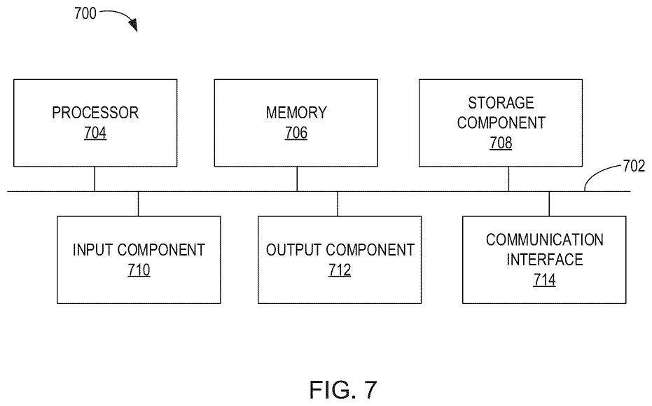

Referring now to FIG. 7, shown is a diagram of example components of a device 700 according to non-limiting embodiments or aspects. Device 700 may correspond to at least one applicator 106a-106c, control system 110, user device 112, and/or analyzer 114a-114c in FIG. 2 and/or at least one of control system 110, substrate identifier 116, coating profile data database 118, coating profiler 120, deviation profiler 122, experimental data database 124, control model 126, instruction generator 128, communication processor 130, and/or color model 132 in FIG. 3, as an example. In some non-limiting embodiments or aspects, such systems or devices in FIGS. 2-3 may include at least one device 700 and/or at least one component of device 700. The number and arrangement of components shown in FIG. 7 are provided as an example. In some non-limiting embodiments or aspects, device 700 may include additional components, fewer components, different components, or differently arranged components than those shown in FIG. 7. Additionally, or alternatively, a set of components (e.g., one or more components) of device 700 may perform one or more functions described as being performed by another set of components of device 700.

As shown in FIG. 7, device 700 may include bus 702, processor 704, memory 706, storage component 708, input component 710, output component 712, and communication interface 714. Bus 702 may include a component that permits communication among the components of device 700. In some non-limiting embodiments or aspects, processor 704 may be implemented in hardware, firmware, or a combination of hardware and software. For example, processor 704 may include a processor (e.g., a central processing unit (CPU), a graphics processing unit (GPU), an accelerated processing unit (APU), programmable logic controller (PLC), etc.), a microprocessor, a digital signal processor (DSP), and/or any processing component (e.g., a field-programmable gate array (FPGA), an application-specific integrated circuit (ASIC), etc.) that can be programmed to perform a function. Memory 706 may include random access memory (RAM), read only memory (ROM), and/or another type of dynamic or static storage device (e.g., flash memory, magnetic memory, optical memory, etc.) that stores information and/or instructions for use by processor 704.

With continued reference to FIG. 7, storage component 708 may store information and/or software related to the operation and use of device 700. For example, storage component 708 may include a hard disk (e.g., a magnetic disk, an optical disk, a magneto-optic disk, a solid state disk, etc.) and/or another type of computer-readable medium. Input component 710 may include a component that permits device 700 to receive information, such as via user input (e.g., a touch screen display, a keyboard, a keypad, a mouse, a button, a switch, a microphone, etc.). Additionally, or alternatively, input component 710 may include a sensor for sensing information (e.g., a global positioning system (GPS) component, an accelerometer, a gyroscope, an actuator, etc.). Output component 712 may include a component that provides output information from device 700 (e.g., a display, a speaker, one or more light-emitting diodes (LEDs), etc.). Communication interface 714 may include a transceiver-like component (e.g., a transceiver, a separate receiver and transmitter, etc.) that enables device 700 to communicate with other devices, such as via a wired connection, a wireless connection, or a combination of wired and wireless connections. Communication interface 714 may permit device 700 to receive information from another device and/or provide information to another device. For example, communication interface 714 may include an Ethernet interface, an optical interface, a coaxial interface, an infrared interface, a radio frequency (RF) interface, a universal serial bus (USB) interface, a Wi-Fi® interface, a cellular network interface, and/or the like.

Device 700 may perform one or more processes described herein. Device 700 may perform these processes based on processor 704 executing software instructions stored by a computer-readable medium, such as memory 706 and/or storage component 708. A computer-readable medium may include any non-transitory memory device. A memory device includes memory space located inside of a single physical storage device or memory space spread across multiple physical storage devices. Software instructions may be read into memory 706 and/or storage component 708 from another computer-readable medium or from another device via communication interface 714. When executed, software instructions stored in memory 706 and/or storage component 708 may cause processor 704 to perform one or more processes described herein. Additionally, or alternatively, hardwired circuitry may be used in place of or in combination with software instructions to perform one or more processes described herein. Thus, embodiments described herein are not limited to any specific combination of hardware circuitry and software. The term “programmed or configured,” as used herein, refers to an arrangement of software, hardware circuitry, or any combination thereof on one or more devices.

It will be readily appreciated by those skilled in the art that modifications may be made to the invention without departing from the concepts disclosed in the foregoing description. Accordingly, the particular embodiments described in detail herein are illustrative only and are not limiting to the scope of the invention, which is to be given the full breadth of the appended claims and any and all equivalents thereof.

What is claimed is:

1. A computer-implemented method for automatically controlling a component of a coating applicator, comprising:
identifying, with at least one processor, a first coated substrate comprising a substrate comprising a surface over which at least one coating layer is positioned, the at least one coating layer positioned over the surface using at least one applicator;
in response to identifying the first coated substrate, determining, with at least one processor, a target coating profile corresponding to the first coated substrate;
determining, with at least one processor, an actual coating profile for the first coated substrate;
generating, with at least one processor, a deviation coating profile for the first coated substrate by comparing the target coating profile to the actual coating profile;
inputting, with at least one processor, the deviation coating profile into a model based on experimental coating control data; and
generating, with the model, at least one control instruction for adjusting at least one component of the at least one applicator based on the deviation coating profile prior to coating a second substrate according to the target coating profile.

2. The computer-implemented method of claim 1, further comprising:
automatically adjusting, with at least one processor, the at least one component of the at least one applicator based on the at least one control instruction.

3. The computer-implemented method of claim 1, wherein the substrate comprises glass.

4. The computer-implemented method of claim 1, wherein the first coated substrate comprises the surface over which a coating stack comprising a plurality of coating layers is positioned.

5. The computer-implemented method of claim 4, wherein the deviation coating profile is determined after a first layer of the coating stack is positioned on the surface but before a second layer of the coating stack is positioned over the first layer.

6. The computer-implemented method of claim 4, wherein the deviation coating profile is determined after the plurality of coating layers of the coating stack are positioned over the surface.

7. The computer-implemented method of claim 1, wherein determining the actual coating profile comprises:
taking, with at least one processor, at least one color measurement of the first coated substrate;
inputting, with at least one processor, the at least one color measurement to a second model based on experimental color to thickness data; and
generating, with the second model, the actual coating profile based on the at least one color measurement.

8. The computer-implemented method of claim 1, wherein the target coating profile and/or the actual coating profile provide a target and/or actual coating thickness for at least one layer of the at least one coating layer relative to a position on the surface.

9. The computer-implemented method of claim 1, wherein the at least one applicator comprises a vacuum coating applicator.

10. The computer-implemented method of claim 9, wherein the vacuum coating applicator comprises at least one gas inlet through which at least one reactive or non-reactive gas is flowed to deposit the at least one coating layer on the surface,
wherein the at least one control instruction comprises a control instruction for adjusting a flow rate of the gas through the at least one gas inlet for depositing a coating layer on the second substrate according to the target coating profile.

11. The computer-implemented method of claim 9, wherein the vacuum coating applicator comprises a magnet bar arranged at a height above the surface to deposit the at least one coating layer on the surface,
wherein the at least one control instruction comprises a control instruction for adjusting the height of the magnet bar above the surface for depositing a coating layer on the second substrate according to the target coating profile.

12. The computer-implemented method of claim 11, wherein the magnet bar comprises a plurality of nodes configured to adjust a height of a section of the magnet bar above the surface, wherein the at least one control instruction comprises a control instruction for only a subset of the plurality of nodes to adjust the height of a corresponding section of the magnet bar above the surface for depositing a coating layer on the second substrate according to the target coating profile.

13. The computer-implemented method of claim 1, wherein the first coated substrate comprises the surface over which a coating stack comprising a plurality of coating layers is positioned, wherein a plurality of applicators are provided, each applicator of the plurality of applicators configured to apply a different layer of the plurality of layers of the coating stack,
wherein generating the at least one control instruction comprises:
determining, with the model, at least one applicator of the plurality of applicators requiring adjustment to obtain the target coating profile based on the deviation coating profile; and
generating, with the model, the at least one control instruction for at least one component of the at least one applicator of the plurality of applicators requiring adjustment to obtain the target coating profile.

14. The computer-implemented method of claim 4, wherein inputting the deviation coating profile into the model comprises inputting coating profile data associated with a first layer of the plurality of layers and a second layer of the plurality of layers,
wherein the at least one control instruction for adjusting the at least one component of the at least one applicator is generated to cause the at least one applicator to apply a first layer of a plurality of layers on the second substrate based on the coating profile data associated with the first layer of the plurality of layers and the second layer of the plurality of layers.

15. The computer-implemented method of claim 1, wherein determining the actual coating profile for the first coated substrate comprises determining a thickness of a first layer of the at least one coating layer, the determined thickness of the first layer of the at least one coating layer different from a thickness for the first layer of the at least one coating layer from the target coating profile,
wherein the at least one control instruction for adjusting the at least one component of the at least one applicator is generated to cause the at least one applicator to apply a first layer of at least one coating layer on the second substrate at a different thickness compared to the determined thickness of the first layer of the at least one coating layer from the first coated substrate.

16. The computer-implemented method of claim 1, wherein the first coated substrate comprises a post-tempered substrate having the actual coating profile formed by heating a pre-tempered first substrate having a pre-tempered coating profile,
wherein generating the at least one control instruction comprises the model:
receiving the input comprising the deviation coating profile;
analyzing experimental coating control data comprising a plurality of historical pre-tempered coating profiles;
determining a first historical pre-tempered coating profile from the plurality of historical pre-tempered coating profiles; and
generating the at least one control instruction for adjusting the at least one component of the at least one applicator to cause the at least one applicator to apply the first historical pre-tempered coating profile to a pre-tempered second substrate.

17. The computer-implemented method of claim 1, further comprising:
determining, with the model, that the at least one component of the at least one applicator is malfunctioning or satisfies a limit based on the deviation coating profile; and
maintenancing the at least one component of the at least one applicator.

18. The computer-implemented method of claim 17, further comprising:
in response to determining that the at least one component of the at least one applicator is malfunctioning or satisfies a limit based on the deviation coating profile, automatically updating the model based on the malfunctioning or satisfaction of the limit by generating a control instruction that distributes an adjustment to a remainder of components of the at least one applicator.

19. The computer-implemented method of claim 1, wherein the first coated substrate comprises a post-tempered substrate having the actual coating profile formed by heating a pre-tempered first substrate having a pre-tempered coating profile,
wherein generating the at least one control instruction comprises the model:
receiving the input comprising the deviation coating profile and the pre-tempered coating profile, the deviation coating profile comparing the target coating profile of the post-tempered substrate to the actual coating profile;
comparing the pre-tempered coating profile to the actual coating profile; and
generating the at least one control instruction for adjusting the at least one component of the at least one applicator based on the comparison of the pre-tempered coating profile to the actual coating profile.

20. A system for automatically controlling a component of a coating applicator, comprising:
at least one applicator configured to prepare a first coated substrate comprising a substrate comprising a surface over which at least one coating layer is positioned; and
a control system comprising at least one processor programmed or configured to:
identify the first coated substrate;
in response to identifying the first coated substrate, determine a target coating profile corresponding to the first coated substrate;
determine an actual coating profile for the first coated substrate;
generate a deviation coating profile for the first coated substrate by comparing the target coating profile to the actual coating profile;
input the deviation coating profile into a model based on experimental coating control data; and
generate, with the model, at least one control instruction for adjusting at least one component of the at least one applicator based on the deviation coating profile prior to coating a second substrate according to the target coating profile.
